(19) United States
(12) Patent Application Publication
(10) Pub. No.: US 2025/0167779 A1
(43) Pub. Date: May 22, 2025

(54) REFERENCE-LESS ELECTRO-THERMAL LOOP WITH WINDOW MONITOR

(71) Applicant: TEXAS INSTRUMENTS INCORPORATED, Dallas, TX (US)

(72) Inventors: Divya Kaur, Delhi (IN); Vinod Menezes, Bangalore (IN); Rajat Chauhan, Bangalore (IN)

(21) Appl. No.: 18/950,397

(22) Filed: Nov. 18, 2024

(30) Foreign Application Priority Data
Nov. 22, 2023 (IN) 202341079227

(51) Int. Cl. H03K 17/14

(52) U.S. Cl. CPC H03K 17/145

(57) ABSTRACT

Some aspects relate to a circuit comprising a temperature-dependent circuit, a proportional to absolute temperature (PTAT) current sink, a complementary to absolute temperature current source (CTAT) current source, and a heating element. The temperature-dependent circuit is disposed within an integrated circuit package. The PTAT current sink is disposed within the integrated circuit package and has an output terminal. The CTAT current source is disposed within the integrated circuit package and has an output terminal coupled to the output terminal of the PTAT current sink. The heating element is disposed within the integrated circuit package and has a control terminal coupled to the output terminal of the PTAT current sink and the output terminal of the CTAT current source.

### CROSS-REFERENCE TO RELATED APPLICATIONS

This application claims the benefit of and priority to India Provisional Application No. 202341079227, filed Nov. 22, 2023, entitled “REFERENCE-LESS ELECTRO-THERMAL LOOP WITH IN-BUILT WINDOW THERMAL MONITOR”, the contents of which are herein incorporated by reference in their entirety.

### BACKGROUND

Some integrated circuits may include an on-chip heater that is used to maintain the integrated circuit at a constant temperature. To provide this functionality, the integrated circuit may have circuits capable of measuring temperature and providing heating to maintain the constant temperature. These circuits on the integrated circuit are used to maintain a desired temperature for other circuits on the integrated circuit that have a temperature dependence.

### SUMMARY

Some aspects relate to a circuit comprising a temperature-dependent circuit, a proportional to absolute temperature (PTAT) current sink, a complementary to absolute temperature current source (CTAT) current source, and a heating element. The temperature-dependent circuit is disposed within an integrated circuit package. The PTAT current sink is disposed within the integrated circuit package and has an output terminal. The CTAT current source is disposed within the integrated circuit package and has an output terminal coupled to the output terminal of the PTAT current sink. The heating element is disposed within the integrated circuit package and has a control terminal coupled to the output terminal of the PTAT current sink and the output terminal of the CTAT current source.

Some aspects relate to a circuit comprising a first current mirror, a first transistor, a second transistor, a differential amplifier, a second current mirror, a third current mirror, and a third transistor. The first current mirror is disposed within a substrate and has a reference terminal and an output terminal. The first current mirror includes transistors of a first polarity. The first transistor is disposed within the substrate and has a first terminal, a second terminal, and a control terminal. The first terminal of the first transistor is coupled to the output terminal of the first current mirror. The control terminal of the first transistor is coupled to the reference terminal of the first current mirror. The first transistor has a second polarity. The second transistor is disposed within the substrate and has a first terminal and a control terminal. The control terminal of the second transistor is coupled to the second terminal of the first transistor. The first terminal of the second transistor is coupled to the reference terminal of the current mirror. The differential amplifier is disposed within the substrate and has a first input terminal, a second input terminal, and an output terminal. The first input terminal of the differential amplifier is coupled to the reference terminal of the first current mirror. The second current mirror is disposed within the substrate and has an output terminal and a reference terminal. The reference terminal of the second current mirror is coupled to the second input terminal of the differential amplifier. The second current mirror includes transistors of a second polarity. The second polarity is opposite to the first polarity. The third current mirror is disposed within the substrate and has a reference terminal and an output terminal. The reference terminal of the third current mirror is coupled to the output terminal of the second current mirror. The output terminal of the third current mirror is coupled to the reference terminal of the second current mirror. The third transistor has a control terminal coupled to the output terminal of the differential amplifier.

Further, some aspects relate to a circuit comprising a CTAT current source, a PTAT current source, a heating element, a comparator, a voltage divider, and an AND gate. The CTAT current source is disposed within a substrate and has an output terminal. The PTAT current source is disposed within the substrate and has an output terminal. The output terminal of the PTAT current source is coupled to the output terminal of the CTAT current source. The comparator is disposed within the substrate and has an input terminal. The input terminal of the comparator is coupled to the output terminal of the CTAT current source. The voltage divider is disposed within the substrate and has an output terminal. The output terminal of the voltage divider is coupled to a second input terminal of the comparator. The AND gate has a first input terminal and a second input terminal. The first input terminal of the AND gate is coupled to an output terminal of the comparator. The second input terminal of the AND gate is coupled to the output terminal of the CTAT current source.

### BRIEF DESCRIPTION OF THE DRAWINGS

FIG. 1A shows an example of a reference-less electro-thermal loop circuit.

FIG. 1B shows waveforms of the operation of the circuit in FIG. 1A.

FIG. 2 shows a theoretical explanation of how the circuit shown in FIG. 1A operates.

FIG. 3A shows an example of a complementary to absolute temperature (CTAT) circuit and a proportional to absolute temperature (PTAT) circuit.

FIG. 3B shows waveforms of the operation of the CTAT circuit and PTAT circuit.

FIG. 4 shows a window monitoring circuit coupled to a reference-less electro-thermal loop circuit, in an example.

FIG. 5 shows waveforms of the operation of the window monitoring circuit.

FIG. 6 shows an example circuit that is equivalent and opposite polarity to the circuit shown in FIG. 4.

### DETAILED DESCRIPTION

Maintaining a chip at a constant temperature can be important to increase the performance of the chip. For example, holding a voltage reference circuit at a constant temperature can improve the accuracy of the voltage reference circuit. Thus, the chip may include circuitry to maintain a constant temperature. For instance, the circuitry can include a temperature measurement circuit coupled to a controller. The controller may also have an input from a reference that functions to provide a voltage indicative of a desired set temperature. However, the reference may have a temperature-voltage dependence that is undesirable.

Thus, a reference-less electro-thermal loop is described. The reference-less electro-thermal loop comprises a first circuit that outputs a current and/or voltage that is proportional to absolute temperature (PTAT), a second circuit that has a current and/or voltage that is complementary to absolute temperature (CTAT). Thus, the first circuit outputs a current or voltage that increases with an increase in temperature, and the second circuit outputs a current or voltage that decreases with an increase in temperature. The reference-less electro-thermal loop also comprises a comparison circuit with high gain and a variable heater. The comparison circuit provides a differential amplification between the first circuit and the second circuit and controls the heater to achieve a constant temperature. Thus, a constant temperature can be achieved without a reference signal.

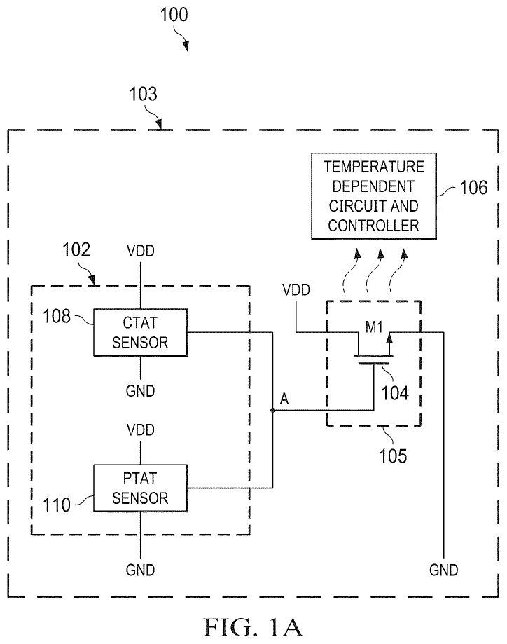

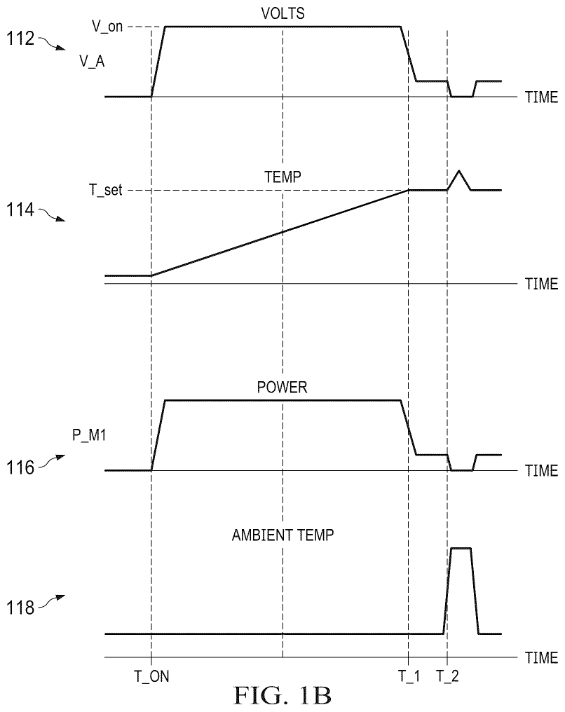

FIG. 1A shows an example of a reference-less electro-thermal loop circuit 100 having a differential absolute-temperature comparator 102 and a heating element 105. The heating element 105 includes a transistor 104. FIG. 1A also shows a temperature-dependent circuit and controller 106. The differential absolute-temperature comparator 102 includes a complementary to absolute temperature (CTAT) circuit 108 and a proportional to absolute temperature (PTAT) circuit 110. The reference-less electro-thermal loop circuit 100 and the temperature-dependent circuit and controller 106 may be within a single integrated circuit package 103. The temperature-dependent circuit and controller 106 may alternatively be just a temperature-dependent circuit, or just a controller, or combination of both.

The CTAT circuit 108 and the PTAT circuit 110 have connections to voltage supply rails VDD and ground (GND). The outputs of the CTAT circuit 108 and the PTAT circuit 110 are coupled to each other. The transistor 104 has a control terminal coupled to the outputs of both the CTAT circuit 108 and the PTAT circuit 110. The transistor 104 has current terminals coupled between the voltage supply rails VDD and ground.

The CTAT circuit 108 outputs a current that decreases with an increase in the temperature, while the PTAT circuit 110 outputs a current that increases with an increase in the temperature. Because the outputs of the CTAT circuit 108 and the PTAT circuit 110 are coupled, the CTAT circuit 108 and the PTAT circuit 110 current limit each other. Also, because the outputs of the CTAT circuit 108 and the PTAT circuit 110 are currents, the combination of their outputs provides an output voltage that has a high gain.

The transistor 104 may have a relatively large size to function as a variable heater. The temperature-dependent circuit and controller 106 may be positioned near the transistor 104. For example, the temperature-dependent circuit and controller 106 may be positioned within the same package as the transistor 104. While the transistor 104 is shown as an n-type metal oxide field effect transistor (MOSFET), other types of transistors may be used. For example, the transistor 104 may be a bi-polar junction transistor (BJT), a junction field effect transistor (J-FET), any other suitable transistor, or a variable resistor.

Because the CTAT circuit 108 and the PTAT circuit 110 generate an output that changes with temperature in different directions, the reference-less electro-thermal loop circuit 100 is able to control the temperature for the temperature-dependent circuit and controller 106 without any reference signal to be used in comparison. The outputs of the CTAT circuit 108 and the PTAT circuit 110 may be current outputs. Thus, the CTAT circuit 108 sources a current, and the PTAT circuit 110 sinks a current or vice versa. The temperature-dependent circuit and controller 106 may be a circuit whose temperature is desired to be maintained. For example, the temperature-dependent circuit and controller 106 may include a reference circuit that has a desired output voltage at a predetermined temperature. The temperature-dependent circuit and controller 106 may alternatively be a clock generation circuit. The reference circuit may be a bandgap reference, a Zener-based reference, a voltage-threshold gap reference, or any other circuit that has a temperature dependence.

FIG. 1B shows the operation of the reference-less electro-thermal loop circuit 100 using a gate voltage graph 112, a temperature graph 114, a power output graph 116, and an ambient temperature graph 118.

The gate voltage graph 112 shows the voltage (V_A) through time at node A, which is coupled to the outputs of the CTAT circuit 108 and the PTAT circuit 110. The temperature graph 114 shows the temperature through time of the reference-less electro-thermal loop circuit 100 and the temperature-dependent circuit and controller 106, and includes a desired set temperature, T_set. The power output graph 116 shows the power output (P_M1) of the transistor 104 through time. The power output of the transistor 104 gets converted to heat. The ambient temperature graph 118 shows the ambient temperature through time of an environment around the reference-less electro-thermal loop circuit 100 and the temperature-dependent circuit and controller 106.

When the circuit receives power and turns on at time T_ON, the temperature of the temperature-dependent circuit and controller 106 is below the desired temperature, T_set, so the differential absolute-temperature comparator 102 provides a control voltage at voltage level V_on to turn on transistor 104. This control voltage to turn on the transistor 104 is shown at the gate voltage graph 112. While the transistor 104 has voltage V_on at its control terminal, the transistor 104 conducts, and emanates heat. This heat emanation is shown in the power output graph 116. Thus, so long as the transistor 104 is on, the power flowing over the transistor 104 causes the chip to heat up, as shown by the temperature graph 114. Thus, during the time period between T_ON and T_1, the differential absolute-temperature comparator 102 provides the control voltage to provide power that actively heats the chip towards the temperature set point T_set.

Eventually, the temperature of the temperature-dependent circuit and controller 106 approaches the desired set temperature T_set, and the combination of the CTAT circuit 108 and the PTAT circuit 110 controls the transistor 104 to be in an equilibrium state. This state is shown between the first time, T_1, and the second time, T_2. During this time between the first time T_1 and the second time, T_2, the amount of power/heating is reduced compared to between T_ON and T_1, and this may be because the temperature of the chip and/or temperature-dependent circuit and controller 106 is about equal to T_set, so limited power/heating is sufficient to keep the chip at an equilibrium state and/or constant temperature.

At the second time, T_2, the ambient temperature increases as shown in the ambient temperature graph 118. This may be due to some outside phenomena that are external to the circuit. This increase in ambient temperature causes the temperature of the temperature-dependent circuit and controller 106 to increase past the desired set temperature as shown in temperature graph 114. Thus, the control voltage to the transistor 104 is reduced as shown in the gate voltage graph 112 and the output power of the transistor 104 is reduced (e.g., to zero) as shown in the power output graph 116. Eventually, the ambient temperature returns to its previous levels as shown in the ambient temperature graph 118, and the rest of the graphs continue as before.

Thus, the reference-less electro-thermal loop circuit 100 is able to control the temperature of the temperature-dependent circuit and controller 106 to be at the desired temperature set point without a reference signal.

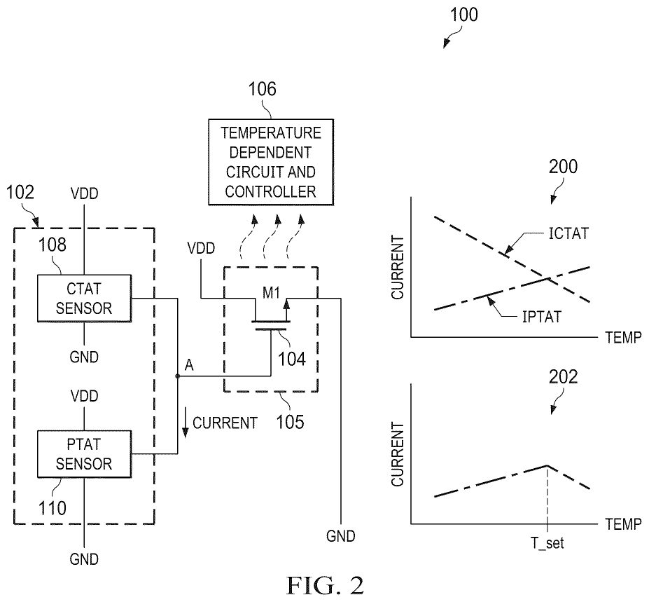

FIG. 2 shows a more detailed example of a reference-less electro-thermal loop circuit 100 of FIG. 1A and graphs illustrating the operating characteristics of the CTAT circuit 108 and the PTAT circuit 110. A separate current temperature graph 200 shows the current temperature characteristic of the CTAT circuit 108 and the PTAT circuit 110 if their outputs are not coupled. A combined current temperature graph 202 shows the current temperature characteristic of the CTAT circuit 108 and the PTAT circuit 110 as they are shown-their outputs being coupled together.

In the separate current temperature graph 200, the current-temperature characteristic of the CTAT circuit 108 is that the current decreases with an increase in the temperature, and the current-temperature characteristic of the PTAT circuit 110 is that the current increases with an increase in temperature. The temperature shown is the absolute temperature, not a relative temperature.

In the combined current temperature graph 202, the current-temperature characteristic is the minimum of the separate current temperature graph 200. This is because the CTAT circuit 108 and the PTAT circuit 110 current limit each other due to Kirchhoff's current law. While the CTAT circuit 108 and the PTAT circuit 110 current limit each other, the circuit that would have had a larger current from the separate current temperature graph 200 determines the voltage to the control terminal of the transistor 104.

For example, below the set temperature, the CTAT circuit 108 may try to output 5 mA, while the PTAT circuit 110 can only output 2 mA, so the CTAT circuit 108 drives the control terminal of the transistor 104 to the positive rail. Alternatively, above the set temperature, the PTAT circuit 110 may try to output 5 mA while the CTAT circuit 108 can only output 2 mA, so the PTAT circuit 110 drives the control terminal of the transistor 104 to the negative rail which is ground.

Because the CTAT circuit 108 and the PTAT circuit 110 are both temperature-dependent current sources, their coupled output becomes a high gain output voltage signal. The output voltage signal is high when below the set temperature, and low when above the set temperature. Thus, the transistor 104 can be used as a heater and controlled by the output voltage signal to maintain a desired temperature.

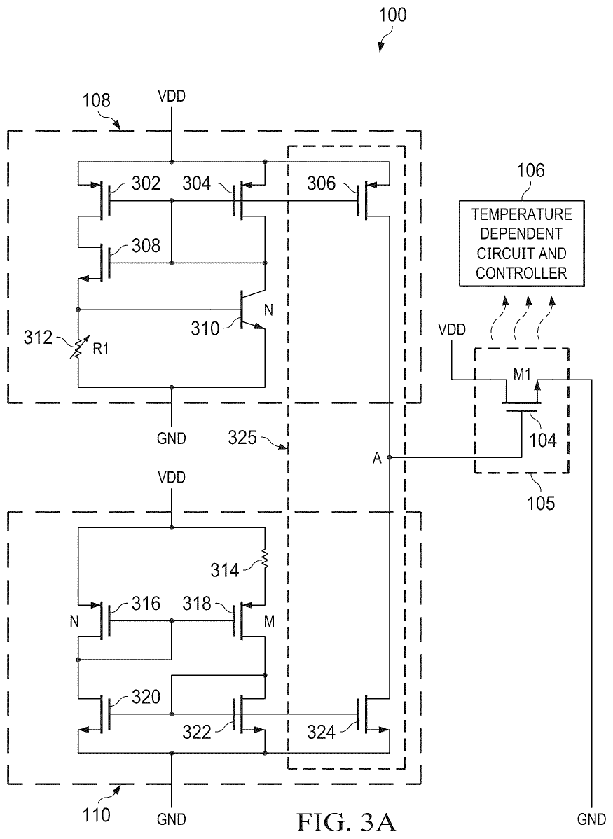

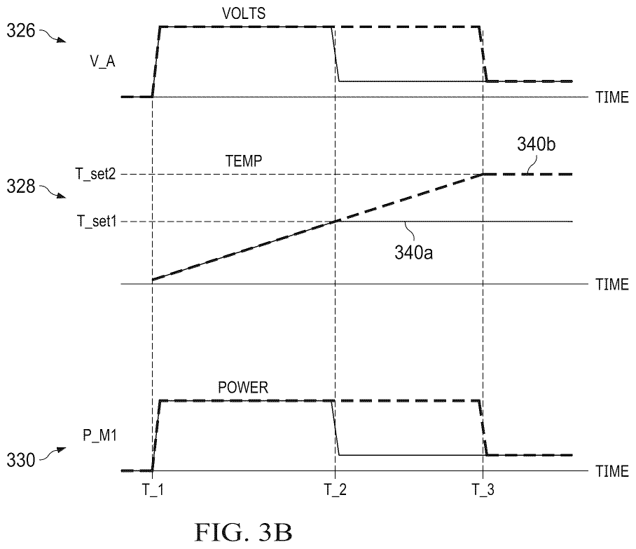

FIG. 3A shows an example implementation of the CTAT circuit 108 and the PTAT circuit 110. The CTAT circuit 108 includes a first transistor 302, a second transistor 304, a third transistor 306, a fourth transistor 308, a fifth transistor 310, and an adjustable resistor 312. The PTAT circuit 110 includes a resistor 314, a sixth transistor 316, a seventh transistor 318, an eighth transistor 320, a ninth transistor 322, and a tenth transistor 324. The third transistor 306 and the tenth transistor 324 may be referred to as a differential amplifier 325.

Within the CTAT circuit 108, the first transistor 302, the second transistor 304, and the third transistor 306 have source terminals and gate terminals coupled to each other to form a current mirror. The current mirror has output terminal at, for example, the drain terminal of the first transistor 302, and has a reference terminal as the drain terminal of the second transistor 304. The first transistor 302 and the fourth transistor 308 have drain terminals and gate terminals coupled to each other to provide positive and negative feedback paths. The fifth transistor 310, which is illustrated as a bipolar junction transistor (BJT), has a current terminal (e.g., collector) coupled to the gate terminal of the first transistor 302, the second transistor 304, and the third transistor 306. The fifth transistor 310 has a second current terminal (e.g., emitter) coupled to the adjustable resistor 312. The fifth transistor 310 has a control terminal (e.g., base) coupled to the other terminal of the adjustable resistor 312 and to the source terminal of the fourth transistor 308. The transistor 104 may have a larger footprint on a substrate compared to the other transistors.

Although the fifth transistor 310 is illustrated as a single transistor, the fifth transistor 310 is implemented as N transistors, all in parallel. Thus, the fifth transistor 310 may be referred to as a group of parallel BJTs whose bases are coupled to one another, whose collectors are coupled to one another, and whose emitters are coupled to one another. Further, the fifth transistor could alternative be a MOSFET, insulated gate field effect transistor (IGFET), or other type of transistor in other examples. The adjustable resistor 312 may be a resistor that is trimmed during the manufacturing of the device or may change while in operation. For example, the adjustable resistor 312 may be a set of fuses that is initially set or may be coupled to a microcontroller and controlled through a communication protocol.

The CTAT circuit 108 operates by generating a temperature-dependent current through the fifth transistor 310 and mirroring that temperature-dependent current to the control terminal of the transistor 104. The first transistor 302 and the fourth transistor 308 provide positive and negative feedback to stabilize the CTAT circuit 108.

Within the PTAT circuit 110, the resistor 314 is coupled between the input voltage and the source terminal of the seventh transistor 318. The sixth transistor 316 has a gate terminal coupled to the gate terminal of the seventh transistor 318 and coupled to the drain terminal of the sixth transistor 316. The drain terminals of the seventh transistor 318 and the sixth transistor 316 are coupled to the drain terminals of the eighth transistor 320, and the ninth transistor 322 respectively. That configuration is called a current mirror. The sixth transistor 316 and the seventh transistor 318 also form a current mirror structure having a supply terminal coupled to the resistor. The eighth transistor 320 and the ninth transistor 322 have source terminals coupled to each other. The ninth transistor 322 has a drain terminal coupled to its gate. The third transistor 306 has a drain terminal coupled to the drain terminal of the tenth transistor 324 and coupled to the control terminal of the transistor 104.

The sixth transistor 316 is repeated N times in parallel, and the seventh transistor 318 is repeated M times in parallel. Because the sixth transistor 316 and the seventh transistor 318 are repeated, they may be referred to as groups of parallel transistors. The difference in lengths of the sixth transistor 316 and the seventh transistor 318 increases the temperature dependence, which generates a current because of the connection with the resistor 314.

The PTAT circuit 110 operates by the combination of the resistor 314 and the seventh transistor 318 generating a current that increases with temperature. The ninth transistor 322 and the tenth transistor 324 functions as a current mirror. The eighth transistor 320 functions as negative feedback, and the sixth transistor 316 functions as positive feedback for an increase in temperature. The combination of the negative feedback and the positive feedback provide stability to the circuit.

The first transistor 302, the second transistor 304, the third transistor 306, the sixth transistor 316, and the seventh transistor 318 are shown as p-type metal oxide field effect transistors (MOSFETs). The fourth transistor 308, the eighth transistor 320, the ninth transistor 322, and the tenth transistor 324 are shown as n-type MOSFETS. The fifth transistor 310 is shown as an n-p-n BJT. All of the transistors shown may be replaced with another transistor type, for example, their BJT, p-type, or n-type equivalent transistor. In some examples, the value of N is four, and the value of M is 52 such that there is a ratio, M/N that is equal to 13. In some examples, the values for N and M may be the same. In other examples, the values for N and M may individually fall within a range. For example, the range for the values for N and M may be between 1 and 100, or between 4 and 20. The adjustable resistor 312 has an arrow drawn through it indicating that the resistor is programmed, trimmed, or set by some means. Alternatively, the resistor 314 may be a variable resistance.

While example circuits are shown for the CTAT circuit 108 and the PTAT circuit 110, other example circuits may be used.

FIG. 3B shows the operating characteristics of the circuit described in FIG. 3A. FIG. 3B includes a voltage graph 326, a temperature graph 328, and a power graph 330. FIG. 3B further includes time callouts to time 1 (T_1), time 2 (T_2), and time 3 (T_3).

The graphs show the operation of the CTAT circuit 108 and the PTAT circuit 110 when the adjustable resistor 312 takes different values. Thus, a manufacturer can manufacture multiple instantiations of FIG. 3A's circuit. The instantiations can have different resistance values. The solid lines (e.g., 340a) are for a first instantiation of FIG. 3A's circuit where the adjustable resistor 312 has been trimmed or set to have a first resistance value, and the dotted lines (e.g., 340b) are for a second circuit that has been trimmed or set to have a second resistance value.

At time T_1, the first instantiation of the circuit receives power and begins to heat up. Thus, from T_1 to T_2, power is provided over transistor M1 104 to raise the temperature of the chip in time. At time T_2, the circuit with the first resistance has achieved its desired set temperature (T_set1), so its heating power is reduced. Thus, at time T_2, there is still some limited amount of power provided over transistor M1 104 to maintain the chip at the temperature T_set1, but this limited amount of power is to offset temperature lost to the ambient environment and keep the chip temperature at substantially constant temperature T_set1. Thus, for the first instantiation of this circuit (e.g., represented by solid lines and line 340a) the adjustable resistor 312 is trimmed to a first resistance value, such that the transistor 104 acts as a variable heater under control of the CTAT circuit 108 and PTAT circuit 110 to maintain the circuit at a first temperature set point T_set1.

In contrast, for the second instantiation of this circuit, the variable resistor 312 has been trimmed to a second resistance value that differs from the first resistance value. This change in resistance changes the temperature set point to T_set2 for the second circuit. Thus, at time T_3, the second instantiation of the circuit has achieved its desired set temperature (T_set2), so its heating power is reduced. Other circuits could also be manufactured with other resistances (and other temperature set points), such that the adjustable resistor 312 can be trimmed to provide customized circuits that are heated to different constant temperature set points for various customers and/or applications. In other examples, the adjustable resistor 312 can even be changed dynamically on a single circuit instantiation for example by a microcontroller or other circuit on chip, such that the temperature set point can change over time for the circuit.

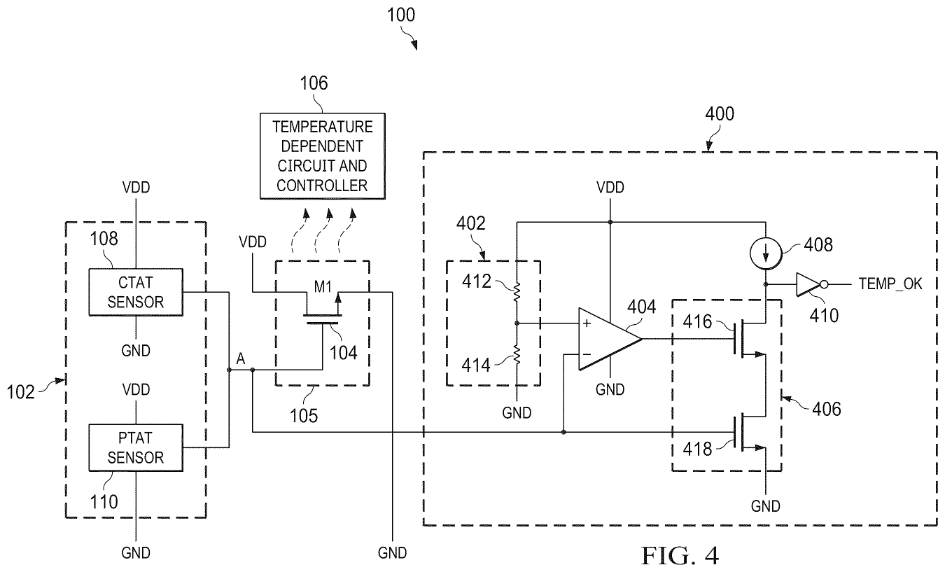

FIG. 4 shows the reference-less electro-thermal loop circuit 100 from FIG. 1A and a window monitoring circuit 400 in an example. The window monitoring circuit 400 has a voltage divider 402, an amplifier 404, an AND gate 406, a current source 408, and an inverter 410. The voltage divider 402 includes a first resistor 412 and a second resistor 414. The AND gate 406 includes a first NMOSFET 416 and a second NMOSFET 418.

The amplifier 404 has a first input coupled to an output of the voltage divider 402 and has a second input coupled to the control terminal of the transistor 104. The AND gate 406 has a first input coupled to the output of the amplifier 404 and a second input coupled to the control terminal of the transistor 104. The current source 408 has an output coupled to an input of the inverter 410 and an input of the AND gate 406. The output of the inverter 410 is the output of the window monitoring circuit 400.

The first NMOSFET 416 and the second NMOSFET 418 are coupled so that their output to the inverter 410 is only low when both the control terminals of the first NMOSFET 416 and the second NMOSFET 418 are high, such that the first NMOSFET 416 and the second NMOSFET 418 form an AND gate. The second NMOSFET 418 is matched to the transistor 104 meaning that the second NMOSFET 418 and transistor 104 have the same lengths and widths as one another, and have the same voltage thresholds as one another, so they turn on at the same time.

The window monitoring circuit 400 operates by providing a temperature-ok signal (TEMP_OK) when the temperature of the temperature-dependent circuit and controller 106 is within a predetermined window of the desired set temperature. The window monitoring circuit 400 achieves this by using the AND gate 406 on two conditions. The first condition is that the transistor 104 is at least partially conducting which is checked by the second NMOSFET 418. The second condition is that the voltage to the control terminal of the transistor 104 is not at one of the rails. The second condition is checked by comparing the voltage at the control terminal of the transistor 104 with a voltage generated somewhere between the rails by using the voltage divider 402. Thus, the circuit detects that both: the transistor 104 is conducting and the control voltage of the transistor 104 is not at a rail. Both of these conditions only occur when the temperature-dependent circuit and controller 106 is near the desired set temperature. For example, in some examples, both of these conditions occur when the temperature-dependent circuit and controller is within 1% of the set temperature, is within 0.1% of the set temperature, or is even within 0.01% of the set temperature. In these and/or others examples, both of these conditions occur when the temperature-dependent circuit and controller is within 5° C. of the set temperature, is within 1° C. of the set temperature, is within 0.1° C. of the set temperature, or even within 0.01° C. of the set temperature. Thus, the differential absolute-temperature comparator 102 can maintain the temperature of the temperature-dependent circuit and controller 106 at unprecedented levels of precision, and the temperature OK signal can be activated in a corresponding manner.

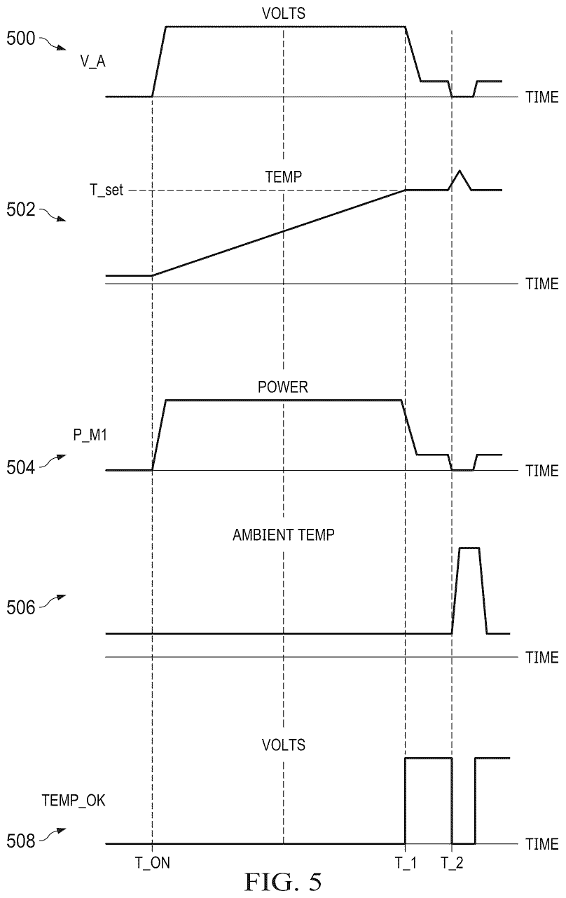

FIG. 5 shows example graphs of the operation of the circuit from FIG. 4. FIG. 5 shows a voltage graph 500, a temperature graph 502, a power graph 504, an ambient temperature graph 506, and a temperature window graph 508. FIG. 5 further shows a time the circuit turns on (T_ON), a first time (T_1), and a second time (T_2).

At T_ON, the circuit turns on and powers the transistor 104 to heat the temperature-dependent circuit and controller 106. Thus, the transistor 104 receives a control voltage as shown in the voltage graph 500, the temperature increases as shown in the temperature graph 502, power is provided as shown in the power graph 504, and the temperature-ok signal (TEMP_OK) is low as shown in the temperature window graph 508. At the first time (T_1), the temperature is approximately equal to the set temperature (T_set). Thus, the reference-less electro-thermal loop circuit 100 reduces the voltage to the control terminal of the transistor 104, which is shown in the voltage graph 500. That causes a reduction in power to the transistor 104 and the temperature-ok (TEMP_OK) signal to go high. The temperature-ok signal indicated that the temperature is near the desired temperature set point.

At the second time (T_2), the ambient temperature increases as shown in the ambient temperature graph 506. This causes the temperature to increase past the desired temperature set point (T_set) as shown in the temperature graph 502. Thus, the control voltage is reduced as shown in the voltage graph 500 which reduces the power for heating as shown in the power graph 504. Also, since the temperature is no longer approximately equal to the desired temperature set point (T_set), the temperature window graph 508 shows the TEMP_OK signal go low. Eventually, the ambient temperature graph 506 shows the ambient temperature decrease and the circuit goes back to normal operation.

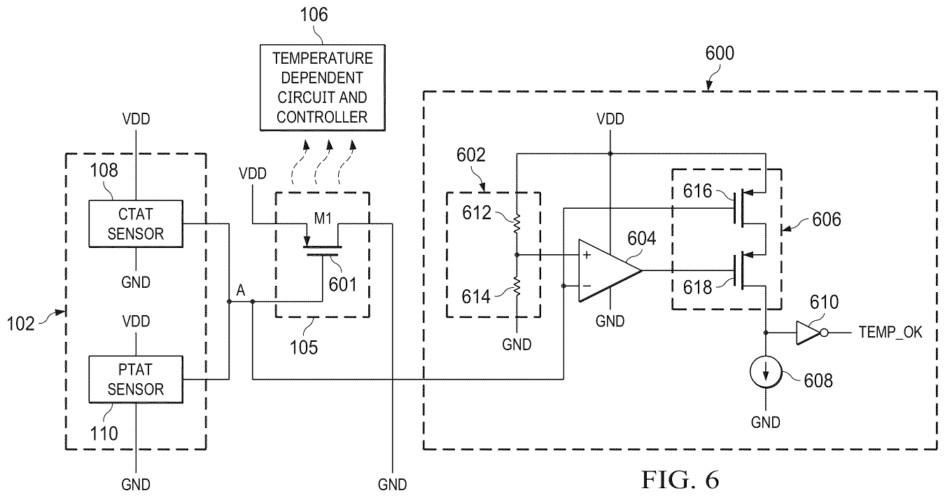

FIG. 6 shows an example of a p-type equivalent circuit to the circuit shown in FIG. 4. FIG. 6 shows a second window monitoring circuit 600 that has a voltage divider 602, an amplifier 604, an AND gate 606, an inverter 610, and a current source 608. Also, the heating element 105 includes a transistor 601 in FIG. 6 that is p-type instead of n-type.

The amplifier 604 has a first input coupled to an output of the voltage divider 602 and has a second input coupled to the control terminal of the transistor 601. The AND gate 606 has a first input coupled to the output of the amplifier 604 and a second input coupled to the control terminal of the transistor 601. The current source 408 has a terminal coupled to the drain terminal of the second PMOSFET 618. The inverter 610 has an input coupled to the drain terminal of the second PMOSFET 618. The output of the inverter 610 is the output of the window monitoring circuit 600. In another example, the output of the window monitoring circuit 600 may be from the drain terminal of the first PMOSFET 616 with a buffer.

The first resistor 612 and the second resistor 614 are coupled together to form a voltage divider. The first PMOSFET 616 and second PMOSFET 618 are coupled so that their output to the inverter 610 is only high when both control terminals of the first PMOSFET 616 and the second PMOSFET 618 are low. Thus, forming an AND gate. The first PMOSFET 616 is matched to the transistor 601 so they turn on at the same time. The circuit shown in FIG. 6 has the same functionality as the circuit shown in FIG. 4.

The methods are illustrated and described above as a series of acts or events, but the illustrated ordering of such acts or events is not limiting. For example, some acts or events may occur in different orders and/or concurrently with other acts or events apart from those illustrated and/or described herein. Also, some illustrated acts or events are optional to implement one or more aspects or embodiments of this description. Further, one or more of the acts or events depicted herein may be performed in one or more separate acts and/or phases. In some embodiments, the methods described above may be implemented in a computer readable medium using instructions stored in a memory.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are illustrated and/or described herein, other transistors (or equivalent switching devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero. Modifications are possible in the described examples, and other implementations are possible, within the scope of the claims.

What is claimed is:

1. A circuit comprising:
a temperature-dependent circuit disposed within an integrated circuit package;
a proportional to absolute temperature (PTAT) current sink disposed within the integrated circuit package and having an output terminal;
a complementary to absolute temperature (CTAT) current source disposed within the integrated circuit package and having an output terminal coupled to the output terminal of the PTAT current sink; and
a heating element disposed within the integrated circuit package and having a control terminal coupled to the output terminal of the PTAT current sink and the output terminal of the CTAT current source.

2. The circuit of claim 1, wherein the heating element is a transistor.

3. The circuit of claim 1, wherein the heating element is an n-type metal oxide field effect transistor (nMOSFET).

4. The circuit of claim 1, wherein the CTAT current source includes a current mirror coupled to a bi-polar junction transistor.

5. The circuit of claim 1, wherein the PTAT current sink includes a first current mirror having transistors of a first polarity, and a second current mirror having transistors of a second polarity, wherein the first polarity is opposite the second polarity.

6. The circuit of claim 1, wherein the CTAT current source includes a current mirror that has three transistors with control terminals coupled to each other.

7. The circuit of claim 1, wherein the PTAT current sink includes a current mirror that has three transistors with control terminals coupled to each other.

8. The circuit of claim 1, wherein the temperature-dependent circuit and controller is a reference circuit.

9. A circuit comprising:
a first current mirror disposed within a substrate and having a reference terminal and an output terminal, the first current mirror including transistors of a first polarity;
a first transistor disposed within the substrate and having a first terminal, a second terminal, and a control terminal, the first terminal of the first transistor coupled to the output terminal of the first current mirror, and the control terminal of the first transistor coupled to the reference terminal of the first current mirror, the first transistor having a second polarity;
a second transistor disposed within the substrate and having a first terminal and a control terminal, the control terminal of the second transistor coupled to the second terminal of the first transistor, the first terminal of the second transistor coupled to the reference terminal of the first current mirror;
a differential amplifier disposed within the substrate and having a first input terminal, a second input terminal, and an output terminal, the first input terminal of the differential amplifier coupled to reference terminal of the first current mirror;
a second current mirror disposed within the substrate and having an output terminal and a reference terminal, the reference terminal of the second current mirror coupled to the second input terminal of the differential amplifier, the second current mirror including transistors of a second polarity, wherein the second polarity is opposite the first polarity;
a third current mirror disposed within the substrate and having a reference terminal and an output terminal, the reference terminal of the third current mirror coupled to the output terminal of the second current mirror, and the output terminal of the third current mirror coupled to the reference terminal of the second current mirror; and
a third transistor having a control terminal coupled to the output terminal of the differential amplifier.

10. The circuit of claim 9, wherein the differential amplifier includes a fourth transistor and a fifth transistor, wherein the fourth transistor and the fifth transistor have opposite polarities.

11. The circuit of claim 10, wherein the fourth transistor has a control terminal coupled to the reference terminal of the first current mirror, and wherein the fourth transistor is of the first polarity.

12. The circuit of claim 11, wherein the fifth transistor has a control terminal coupled to the reference terminal of the second current mirror, and wherein the fifth transistor has the second polarity.

13. The circuit of claim 9, further comprising:
a variable resistor having a first terminal coupled to the control terminal of the second transistor, and having a second terminal coupled to a second terminal of the second transistor.

14. The circuit of claim 13, further comprising:
a resistor having a terminal coupled to a supply terminal of the third current mirror.

15. The circuit of claim 9, wherein the third transistor has a larger footprint on the substrate compared to the first transistor.

16. A circuit comprising:
a CTAT current source disposed within a substrate and having an output terminal;
a PTAT current source disposed within the substrate and having an output terminal coupled to the output terminal of the CTAT current source;
a heating element disposed within the substrate and having a control terminal coupled to the output terminal of the CTAT current source;
a comparator disposed within the substrate and having an input terminal coupled to the output terminal of the CTAT current source;
a voltage divider disposed within the substrate and having an output terminal coupled to a second input terminal of the comparator; and
an AND gate having a first input terminal coupled to an output terminal of the comparator, and having a second input terminal coupled to the output terminal of the CTAT current source.

17. The circuit of claim 16, wherein the AND gate comprises a first transistor and a second transistor.

18. The circuit of claim 17, wherein the first transistor and the second transistor are both NMOS.

19. The circuit of claim 18, wherein the first transistor and the second transistor are both PMOS.

20. A circuit comprising:
a temperature-dependent circuit and controller disposed in a package and having an output at a predetermined temperature;
a variable heater disposed in the package and having a control terminal; and
a differential absolute-temperature comparator disposed in the package and having an output terminal coupled to the control terminal of the variable heater, wherein the differential absolute-temperature comparator is configured to:
source a first current to the control terminal of the variable heater that increases with an increase in temperature; and
sink a second current from the control terminal of the variable heater that decreases with an increase in temperature,
wherein the first current equals the second current at the predetermined temperature.

21. The circuit of claim 20, wherein the differential absolute-temperature comparator comprises a first current source and a second current source.

22. The circuit of claim 20, wherein the temperature-dependent circuit and controller is a clock generation circuit.
